(19) United States
(12) Patent Application Publication
(10) Pub. No.: US 2013/0147716 A1
(43) Pub. Date: Jun. 13, 2013

(54) Computer Receptacle

(71) Applicants: Christopher Hawker, Columbus, OH (US); Jessica Moreland, Columbus, OH (US)

(72) Inventors: Christopher Hawker, Columbus, OH (US); Jessica Moreland, Columbus, OH (US)

(21) Appl. No.: 13/315,614

(22) Filed: Dec. 9, 2011

(51) Int. Cl. G06F 3/02; G06F 1/16; H05K 7/00

(52) U.S. Cl. 345/168; 108/43; 361/679.02

(57) ABSTRACT

A computer receptacle is disclosed herein, including a platform configured to temporarily receive an electronic device having a trough disposed upon a portion thereof, wherein at least a portion of the trough has two substantially parallel walls operatively configured to retain the electronic device therebetween.

Further, a stand is disclosed herein, wherein a stand includes at least a foot portion configured to be pivotably coupled to a telescoping vertical column which in turn is pivotably coupled to a platen configured to temporarily retain a device thereupon.

### BACKGROUND AND TECHNICAL FIELD

The present disclosure pertains at least to portable computer retaining systems and devices.

In certain instances, this can be understood to refer to subject matter comprising (a) housings, boxes, panels, or mounting arrangements with an electrical device, multiple electrical devices, or diverse electrical components or (b) housing or mounting arrangements with keyboards, CRTs, disk drive units, displays, or computer related equipment which inherently have diverse electrical components.

In certain other instances, this can be understood to subject matter comprising support structures for such electronic devices.

### SUMMARY

According to certain embodiments of the present disclosure described herein, a computer receptacle comprises a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the ventral face thereof has a surface configured to be rested comfortably upon the lap of a user.

According to certain embodiments of the present disclosure described herein, the engagement portion further comprises a lateral trough that traverses a substantial portion of the breadth of the receptacle.

According to certain embodiments of the present disclosure described herein, the distance between the opposing walls or a portion thereof may be decreased by a mechanism selected from, a bolt threaded into one of the walls, an eccentrically hinged lever pivotably coupled to one of the walls, or inserts having varying thickness.

According to certain embodiments of the present disclosure described herein, there is a plurality of keys disposed upon the proximal-end portion of the dorsal face of the body, and the keys are electronically connected to the computer to provide input thereto.

According to certain embodiments of the present disclosure described herein, the means of electronic connection is selected from one of the following; a bluetooth connection, an infra-red connection, a wired usb connection, a wired proprietary connection.

According to certain embodiments of the present disclosure described herein, there is a keyed slot disposed upon the ventral face of the body and operatively configured for receiving a stand therein.

According to certain embodiments of the present disclosure described herein, the body has an electrical connector operatively configured to provide electrical, audio, or data communication with a source external to the computer receptacle.

According to certain embodiments of the present disclosure described herein, the connector is selected from the group of, a wire and plug protruding from the body, a plug protruding from the body, at least two electrical contacts disposed upon the body, or an inductive coil.

According to certain embodiments of the present disclosure described herein, the ventral surface comprises at least one of the following; a padded portion of material providing a more complaint surface than the remainder of the receptacle, a portion of natural or synthetic fabric, at least one detent shaped to accommodate a portion of the thigh of a user, a textured surface comprised of a pattern of embosses or detents along the ventral face of the receptacle.

According to certain embodiments of the present disclosure described herein, a computer receptacle comprises a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the opposing walls may be radially displaced relative to the remainder of the body about coaxial pivots A and B disposed upon opposing sides of the body, wherein one of the pivots further comprises a toothed gear, and there is a complimentary toothed arc disposed upon the body which may be temporarily engaged upon the gear, thereby releasably fixing the angle of incidence of the electronic device relative to the body; and the ventral face thereof has a surface configured to be rested comfortably upon the lap of a user.

According to certain embodiments of the present disclosure described herein, there is a spring biasing the arc towards the gear.

According to certain embodiments of the present disclosure described herein, there is a spring biasing the arc away from gear.

According to certain embodiments of the present disclosure described herein, there is an eccentrically hinged lever pivotably coupled to the body, with the lever having a bearing face A such that at one extreme of the lever's rotation, A engages the arc against the gear and at its other extreme of the lever's rotation, withdraws the arc from contact with the gear.

According to certain embodiments of the present disclosure described herein,there is a plurality of keys disposed upon the proximal-end portion of the dorsal face of the body, and the keys are electronically connected to the computer and providing electronic input.

According to certain embodiments of the present disclosure described herein, the means of electronic connection is selected from one of the following; a bluetooth connection, an infra-red connection, a wired usb connection, a wired proprietary connection.

According to certain embodiments of the present disclosure described herein, there is a keyed slot disposed upon the ventral face of the body and operatively configured for receiving a stand therein.

According to certain embodiments of the present disclosure described herein, a computer receptacle comprises a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the distance between the opposing walls or a portion thereof may be decreased by a mechanism selected from, a bolt threaded into one of the walls, an eccentrically hinged lever pivotably coupled to one of the walls, or inserts having varying thickness, and the opposing walls may be radially displaced relative to the remainder of the body about coaxial pivots A and B disposed upon opposing sides of the trough, wherein one of the pivots further comprises a toothed gear, and there is a complimentary toothed arc disposed upon the body which may be temporarily engaged upon the gear, thereby releasably fixing the angle of incidence of the electronic device relative to the body; and the ventral face thereof has a surface configured to be rested comfortably upon the lap of a user.

According to certain embodiments of the present disclosure described herein, there are a plurality of keys disposed upon the dorsal surface of the body and electronically connected to the computer.

According to certain embodiments of the present disclosure described herein, the angle of incidence between the parallel walls and the body is adjustable by means of a selectively engageable, radially hinged mechanism.

According to certain embodiments of the present disclosure described herein, the distance between the opposing walls or a portion thereof may be decreased by a mechanism selected from, a bolt threaded into one of the walls, an eccentrically hinged lever pivotably coupled to one of the walls

### BRIEF DESCRIPTION OF THE FIGURES

In the figures, which are not necessarily drawn to scale, like numerals describe substantially similar components throughout the several views. The drawings illustrate generally, by way of example, but not by way of limitation, various embodiments discussed in the claims of the present document.

FIG. 1 shows an isometric view of an embodiment of a computer receptacle.

FIG. 2 shows an exploded isometric view of the embodiment of a computer receptacle shown in FIG. 1.

FIG. 3 shows an isometric view of an embodiment of a chassis.

FIG. 4 shows an isometric view of an embodiment of a retaining portion.

FIG. 5 shows a first configuration of an embodiment of the present disclosure retaining a portable computer.

FIG. 6 shows a second configuration of an embodiment of the present disclosure retaining a portable computer.

FIG. 7 shows a cut-away detail elevation view of an embodiment of a lever lock in a first configuration.

FIG. 8 shows a cut-away detail elevation view of an embodiment of a lever lock in a second configuration.

FIG. 9 shows an exploded isometric view of an embodiment of the present disclosure further comprising a stand.

FIG. 10 shows an isometric view of an embodiment of the present disclosure.

FIG. 11 shows an isometric view of the underside of a chassis as it is coupled to a stand.

FIG. 12 shows an exploded isometric view of the underside of a chassis as it is coupled to a stand.

FIG. 13 shows an isometric view of a stand in a first, collapsed configuration.

FIG. 14 shows an isometric view of a stand in three possible collapsed, tilted configurations.

FIG. 15 shows an isometric view of a stand with a column in a second, extended configuration.

FIG. 16 shows an isometric view of a stand in three possible extended, tilted configurations.

FIG. 17 shows a cut-away view of an embodiment of a locking mechanism in a first configuration.

FIG. 18 shows a cut-away view of an embodiment of a locking mechanism in a second configuration.

FIG. 19 shows an isometric view of an embodiment of the present disclosure.

### DETAILED DESCRIPTION OF THE FIGURES

Various embodiments of the presently disclosed apparatus will now be described in detail with reference to the drawings, wherein like reference numerals identify similar or identical elements. In the drawings and in the description that follows, the term “proximal,” will refer to the end of a device or system that is closest to the operator, while the term “distal” will refer to the end of the device or system that is farthest from the operator.

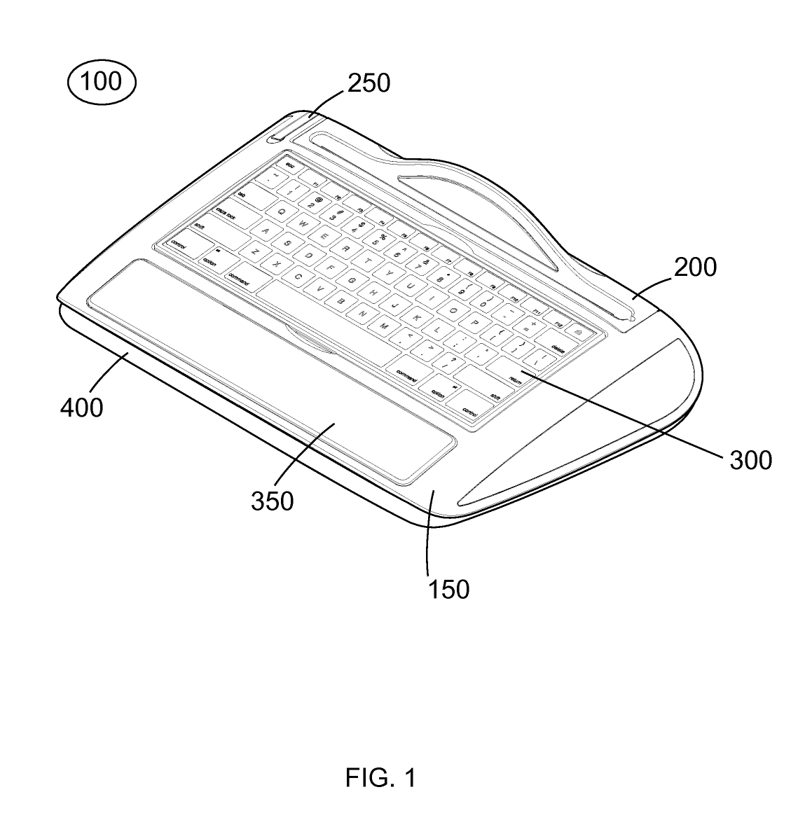

With reference to FIG. 1, an embodiment of the present disclosure is shown wherein a computer holder 100 comprises a chassis 150, a retaining portion 200, a lever lock 250, a keyboard 300, a palm rest 350, and a bottom pad 400.

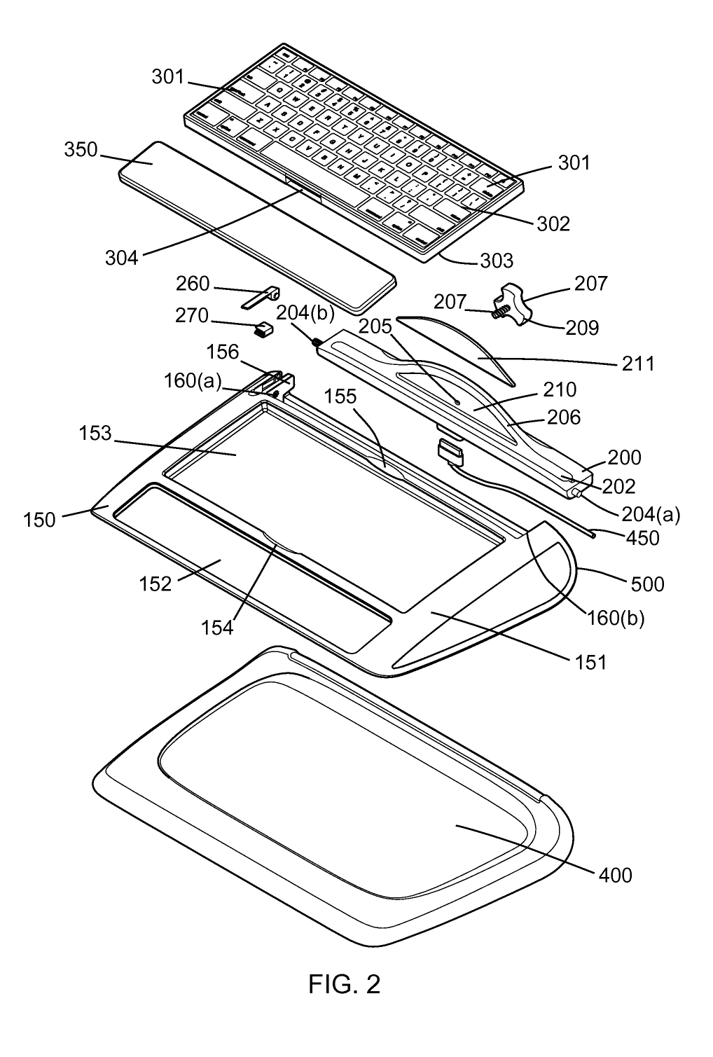

Referring now to FIG. 2, chassis 150 is a rigid, substantially planar member having a substantially triangular cross section with a plurality of features disposed thereupon configured for coupling with the several components of the embodiment of the present disclosure shown in the figures. Specifically, chassis 150 has recesses 152, 153, and 156 removed from a top surface 151 thereof configured to removably receive palm rest 350, keyboard 300, and retaining portion 200 respectively therein.

According to the embodiment of the present disclosure shown in the figures, palm rest 350 is a substantially planar, rectangular member composed of for instance a rigid plastic, a deformable closed-cell foam, or a deformable gel. According to certain embodiments of the present disclosure, the surface of palm rest 350 is covered with a natural or synthetic fabric, or textured surface finish. Recess 152 disposed on chassis 150 is operatively configured to receive and retain palm rest 350 therein such that a top surface of palm rest protrudes slightly from top surface 151.

Although in the embodiment shown in the figures the top surface of palm rest 350 protrudes slightly from top surface 151, there are further embodiments of the present disclosure wherein the top surface of palm rest 350 is alternatively recessed below top surface 151 or flush with top surface 151. Palm rest 350 may be removably retained within recess 152 by way of friction-fitting, adhesive, hook/loop fasteners, magnetic couplers, or other temporary fixation methods known in the manufacturing arts.

With continued reference to FIG. 2, keyboard 300 is a substantially planar member having a array of touch triggers 301 disposed on a top surface 302 thereof, and a substantially uninterrupted face disposed on an opposing bottom surface 303 thereof. There is a complimentary recess 153 removed from top surface 151 of chassis 150 operatively configured to retain keyboard 300 therein.

With continued reference to FIG. 2, there is a finger detent 304 disposed upon the long axis of at least one side of keyboard 300. Further, there are complimentary recesses 154 and 155 disposed upon the corresponding long axis of recess 153 operatively configured to expose detent 304 when keyboard 300 is inserted into recess 153 thereby allowing a user to reach detent 304 with his finger when keyboard 300 has either top surface 302 or bottom surface 303 exposed.

Referring now to FIG. 4, retaining portion 200 comprises an elongated body 201 having a recess 202 substantially disposed along the long axis thereof. Recess 202 has opposing parallel sides 210 and 211 operatively configured for receiving a computer therebetween, including for instance a tablet computer, portable data assistant, electronic reader, cellular telephone, or other substantially planar suitable device known in the art. There is an elevated portion 206 extending from a top surface 203 of retaining portion 200. Elevated portion 206 is a substantially solid projection having a substantially arcuate profile configured to provide operative support for a device inserted into recess 202. Further, there is a pad recess 212 disposed upon a proximal face of retaining portion 200.

Although in the embodiment shown in the figures, recess 202 spans substantially the entire width of the chassis, there are further embodiments of the present disclosure, wherein the parallel walls of a recess may be substantially interrupted such as to provide a set of contact points for inserting an electronic device therein as opposed to an uninterrupted surface as shown in the figures.

Elevated portion 206 has a threaded hole 205 extending therethrough operatively configured to receive a complimentary knob 207 therein. Knob 207 is an elongated rigid member having a distal end portion and a proximal portion. There is a threaded rod 208 disposed upon the proximal end portion of knob 207 configured to be received and retained within threaded hole 205. Further, there is a gripping area 209 disposed at the distal end portion of knob 208 configured to enable a user to rotate knob 207 about an axis X. There is also a contact pad 211 disposed within pad recess 212 operatively coupled to the proximal-most portion of threaded rod 208.

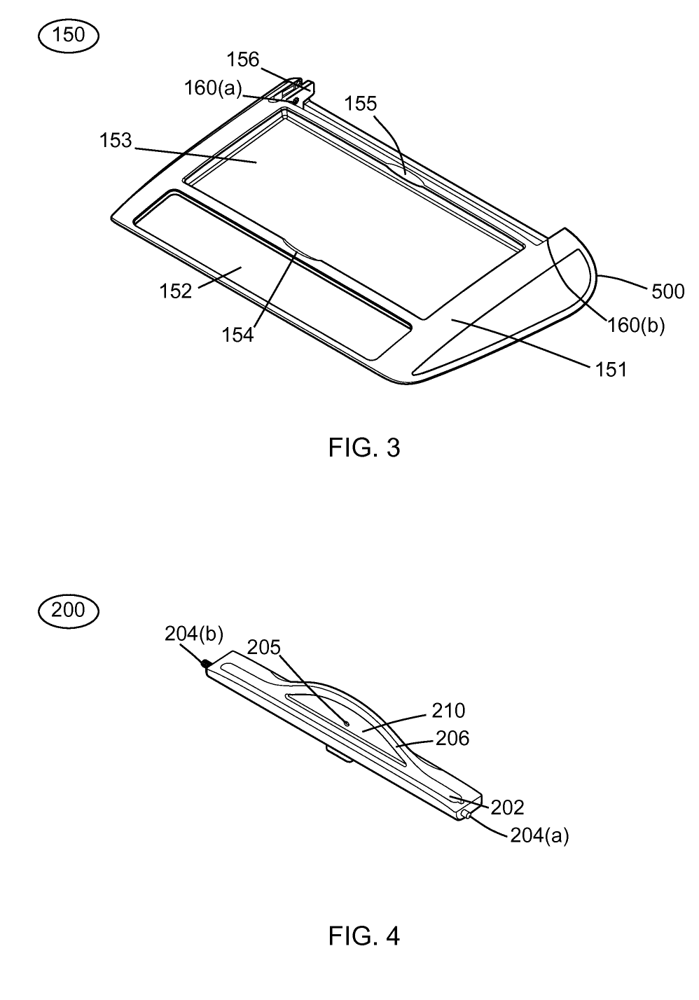

Returning now to FIG. 3, there is a wire connector 450 disposed within recess 202 electrically coupled to a complimentary power and data connector 500 disposed at the rear of chassis 150 as shown in FIG. 4. Wire connector is configured to provide electronic coupling between a device placed in recess 202. Coupling includes for instances, a power source including home alternating current, regulated direct current, data upload or download streams, audio connectivity, antenna augmentation, or other electronic peripheral connectivity known in the art. According to further embodiments of the present disclosure not shown in the figures, wire connector 450 also provides electronic coupling between a device inserted into recess 202 and keyboard 300. There are further embodiments of the present disclosure wherein electronic coupling between the computer receptacle and a device located therein are achieved without the use of physical connectivity including for instance, radio and/or bluetooth connectivity, capacitive charging, and other wireless transmission methods known in the arts.

According to still further embodiments of the present disclosure not shown in the figures, there are amplified speakers disposed within chassis 150 configured to reproduce and amplify audio signals propagated through wire connector 450.

With returning reference to FIG. 2, there are pivots 204(a, b) extending coaxially from opposing faces of retaining portion 200. Co-axial pivots 204(a, b) are configured to be rotatably retained within complimentary holes 160(a, b) disposed upon chassis 150.

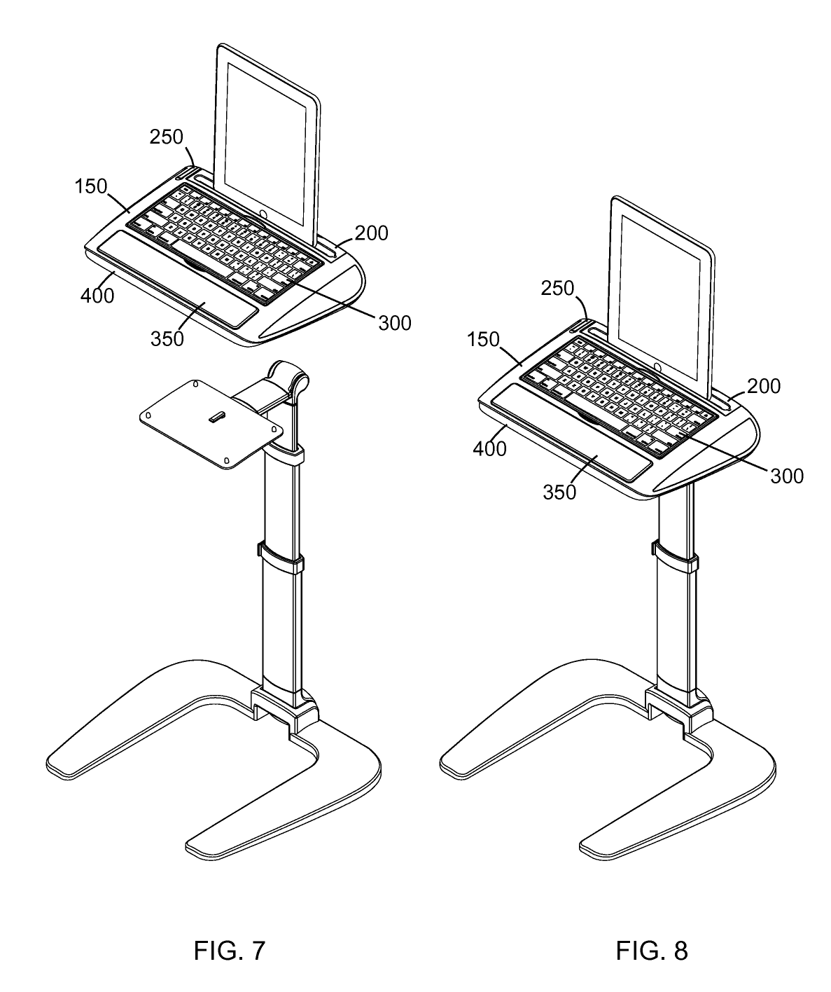

Referring now to FIGS. 7 and 8, there is a level lock mechanism 250 disposed at one side of chassis 150. Lever lock mechanism 250 comprises a lever 260, a retention spring 266, and a coupling arm 270.

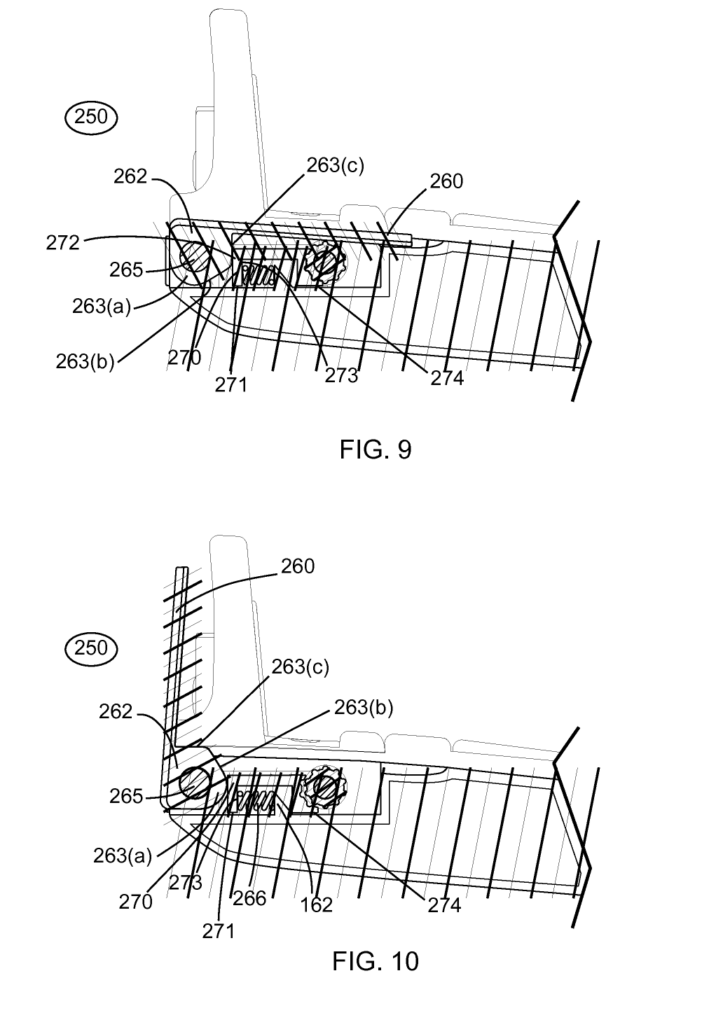

With continued reference to FIG. 9, lever 260 is an elongated member having a distal end portion and a proximal end portion. There distal body 262 disposed upon the distal end portion of lever 260. Distal body 262 has a eccentric pins 265(a, b) extending laterally from opposing sides thereof and rotatably coupled to a corresponding holes 165(a, b) disposed upon chassis 150. There are bearing surfaces 263(a, b, and c) disposed upon distal body 262 at respectively increasing distances from the center of eccentric pin 165.

There is an elongated coupling arm 270 disposed between distal body 262 and pivot 204(b) slideably coupled to a corresponding channel 161 within chassis 150. Elongated coupling arm is an elongated member having a distal end portion and a proximal end portion. The distal end portion of coupling arm 270 has a distal projection 271 extending downward in a substantially orthogonal relation to its direction of travel and having opposing faces 272 and 273 disposed thereupon. The proximal end portion of coupling arm 270 has a proximal projection 274 extending downward in a substantially orthogonal relation to coupling arm 270's direction of travel. Proximal projection 274 has a proximal face with a substantially arcuate profile and a plurality of detents 275(a-d) disposed thereupon configured to temporarily interfere with corresponding protrusions disposed about the circumference of pin 204(b).

With continued reference to FIGS. 7 and 8, there is a retaining protrusion 162 disposed upon chassis 150 having a face 163 in substantially orthogonal relation to the travel of coupling arm 270. There is a retention spring 266 disposed between face 163 and face 273 providing a separating biasing force thereagainst.

With reference to FIG. 11, there is a bottom pad 400 disposed upon the underside of chassis 150 and removably coupled thereto. Pad 400 may be rigid or composed of a deformable material such as a gel, foam, or filled with a granular filler. According to further embodiments of the present disclosure, Pad 400 is covered in a natural or synthetic fabric.

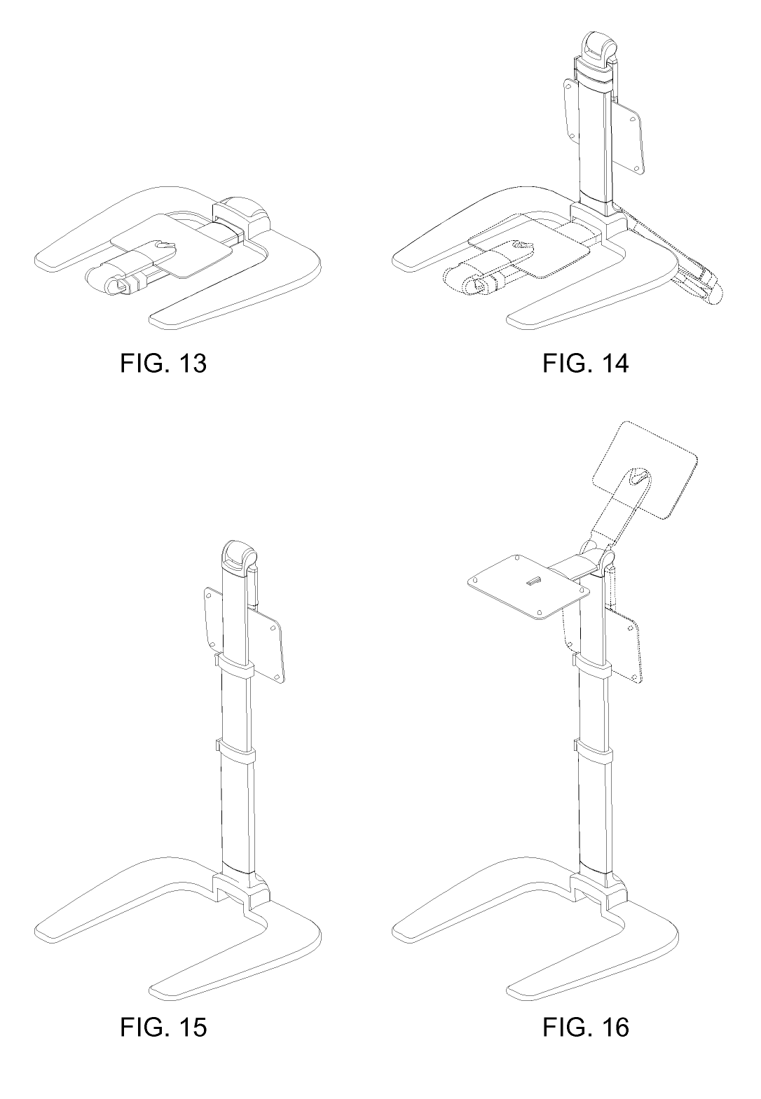

With reference to FIG. 9, a receiving stand 600 comprises a base 650, a column 700, an armature 750, and a platen 800. Base 650 is a substantially planar member having a pair of substantially symmetrical curved planar feet 651 and 652 extending in opposing directions from a junction 653 and thereby substantially approximating a “horseshoe.” There is an elevated pivot 654 disposed above junction 653 which provides operative and pivoting support for a lowermost portion 701 of column 700. According to the embodiment of the present disclosure shown in the figures, elevated pivot 654 has a portion removed from the proximal face thereof configured to allow column 700 to be folded forward as shown in FIG. 13.

With continued reference to FIG. 9, column 700 is an elongated annular member having at least a first annulus 702 and a second annulus 703 with a locking coupler 704 disposed therebetween. The aforementioned annulae are configured such that second annulus 703 is configured to be slideably inserted into first annulus 702. According to the configuration of an embodiment of the present disclosure shown in FIG. 9, after second annulus 703 may be inserted into first annulus 702 and fixed relative to first annulus 704 by locking coupler 704 thereby approximating a telescoping and adjustable column. As shown in FIG. 9, there may be additional annulae and corresponding couplers defining additional telescoping sections of the assembly.

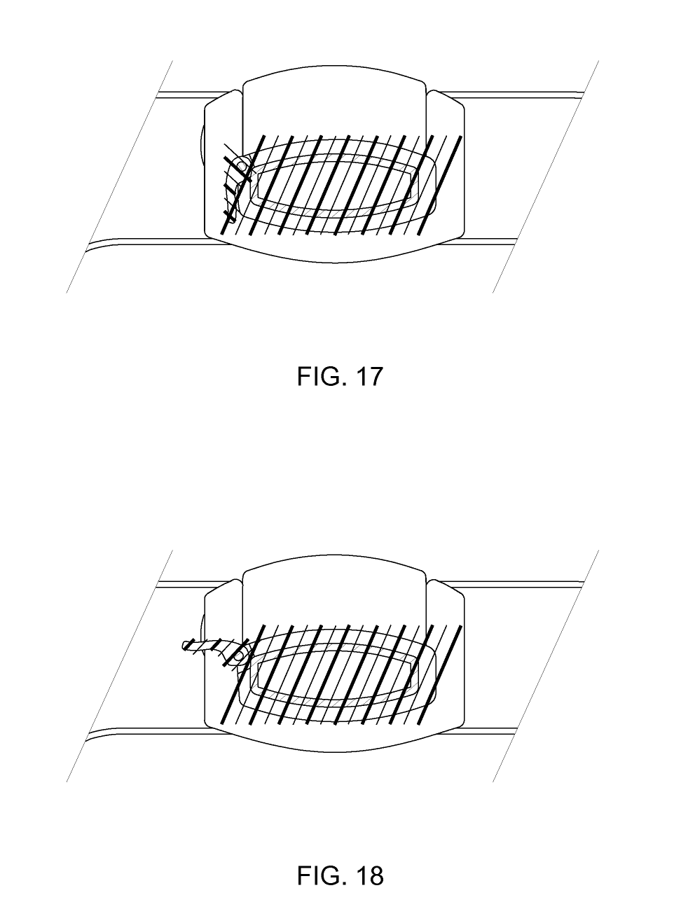

With reference to FIGS. 17 and 18, detail section views of locking coupler 704 is provided wherein locking coupler 704 is coupled to first annulus 702. There is an eccentrically disposed cam 706 configured to rotate about a pivot 705. Such that in a first configuration, as shown in FIG. 17, a portion of cam 706 interferes with second annulus 703 thereby temporarily fixing the relative vertical position of the annulae relative to one another. In a second configuration, as shown in FIG. 18, cam 706 may be rotated about pin 705 such that no portion of cam 706 significantly interferes with second annulae 703 thereby allowing the annulae to be displaced relative to one another.

With continued reference to FIG. 9, column 700 has pivot 705 and pivot 706 disposed at the respective top and bottom end portions thereof. Pivots 705 and 706 are configured to pivotably couple column 700 to base 650 and armature 750 respectively. Additionally, there may be detents disposed upon the interface of pivots 705 and 706 configured to interfere with corresponding structures upon armature 750 and base 650 thereby providing a plurality of configurations about the rotational path of each pivot.

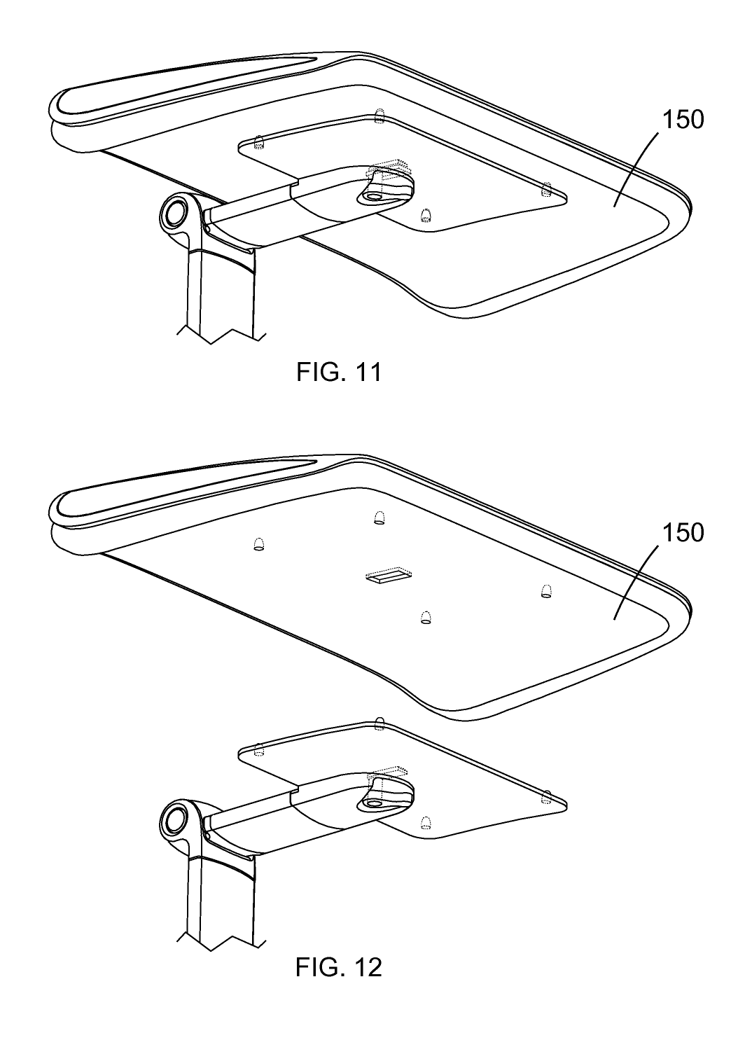

Referring now to FIG. 12, an armature 750 comprises a pivot 751, a extension 752, a head 753, and a lock 760. Pivot 751 comprises an englarged member pivotably coupled to column 700 in the manner described in the preceding paragraph. Pivot 751 provides operative support for extension 752, which in turn provides operative support for head 753. Head 753 comprises the proximal-most portion of armature 750 and has a portion removed from the underside thereof defining recess 754. Recess 754 is configured to allow limited angular displacement of lock 760.

With continued reference to FIG. 12, a platen 800 is a substantiallly planar member configured to provide operative support for either bottom pad 400 or the underside of chassis 150. There are a plurality of protrusions 801(a-d) operatively configured to be received within complimentary recesses 158(a-d) disposed upon either bottom pad 400 or the underside of chassis 150.

Referring now to FIG. 11, lock 760 comprises a lower lever portion 761, a pin 762, and a upper tab 763 rigidly coupled to one another. Lever portion 761 is a rigid member extending in substantially orthogonal relation from pin 762 operatively configured to rotate lock 760 about a long axis “L” of pin 762. Pin 762 traverses a complimentary hole through head 753 and platen 800 thereby defining an axis L. Upper tab 763 is an elongated structure operatively configured to frictionally and temporarily engage a corresponding recess 157 disposed on the underside of chassis 150.

A method of using the embodiment of the present disclosure shown in the figures will now be described.

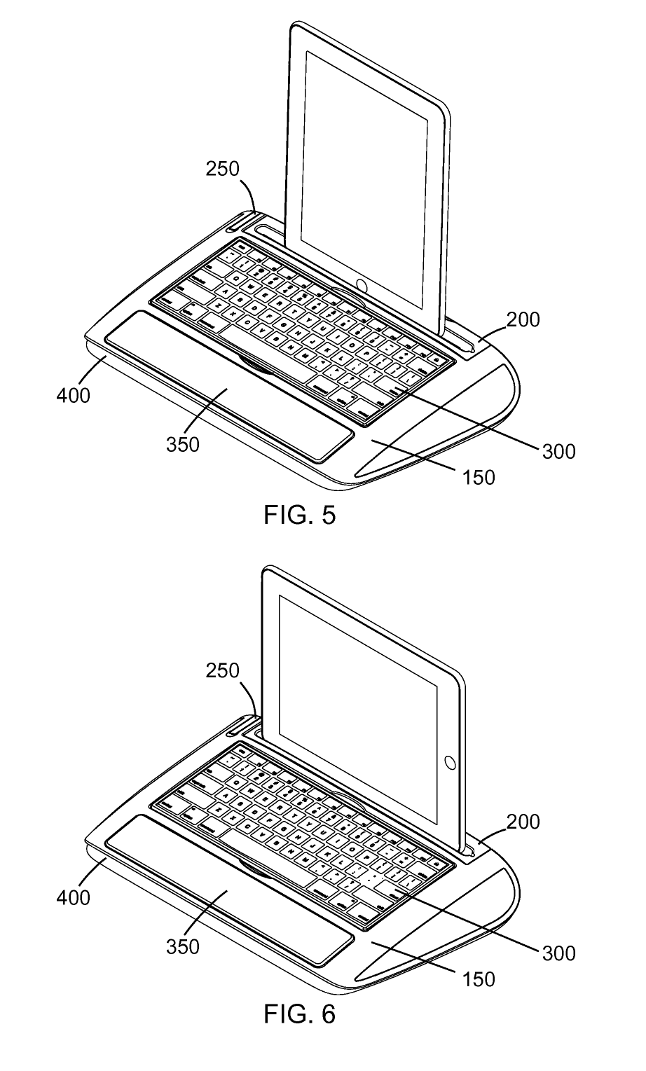

A computer receptacle 100 is provided in a first state as shown in FIG. 1. Next, a user may connect connector 450 to provide power, data, or audio connectivity between receptacle 100 and a planar computing device 1000. Next, a user may insert a planar computing device 1000 into trough 202 in either a portrait configuration as shown in FIG. 5 or a landscape configuration as shown in FIG. 6. Upon satisfactory orientation of planar computing device 1000 in trough 202, a user may secure planar computing device 1000 therein by rotating knob 207 relative to chassis 150 thereby abutting pad 211 against a rear face of planar computing device 1000 and consequently temporarily fixing planar computing device 1000 between pad 211 and trough 202.

Next, if a user desires to tilt planar computing device relative to chassis 150, he may lift lever 260 in the configuration shown in FIG. 8, thereby disengaging detents 275(a-d) from pin 204(b) thereby allowing retaining portion 200 and consequently planar computing device 1000 to rotate about pins 204(a and b) until the device is configured in a satisfactory orientation. Upon such configuration, lever 260 may then be returned to the first state, shown in FIG. 7, wherein detents 275(a-d) again engage pin 204, thereby substantially fixing retaining portion 200 relative to chassis 150.

A method of using the embodiment the present disclosure in conjunction with a stand will now be described.

Referring now to FIGS. 11 and 12, a computer receptacle 100 may be coupled to a stand 600 by inserting projections 801(a-d) into corresponding recesses 158(a-d). Receptacle 100 may be subsequently fixed to stand 600 by rotating lever 761 relative to stand 600 about pin 762 thereby temporarily engaging upper tab 763 against recess 157.

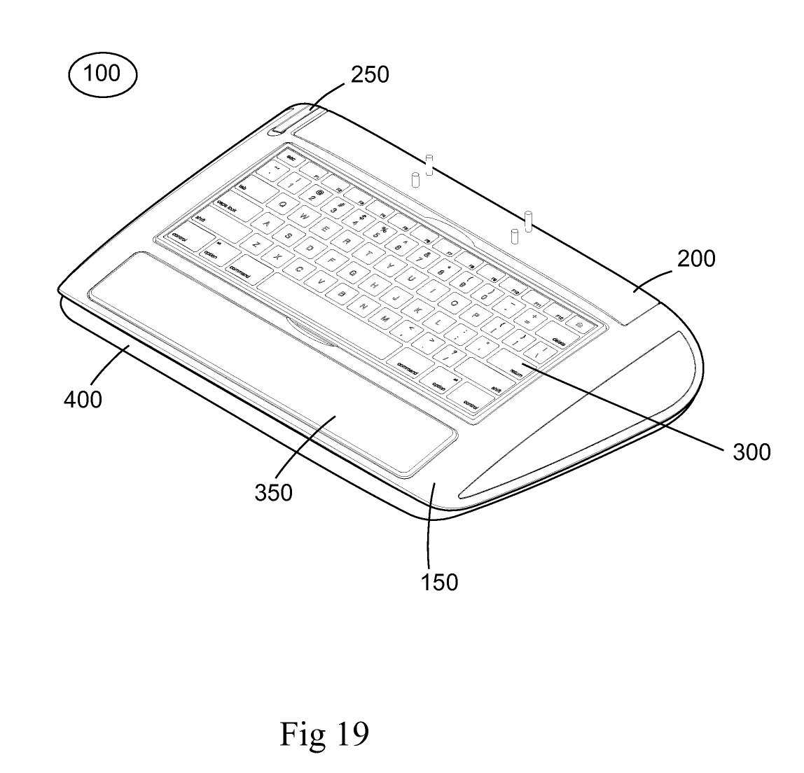

Referring now to FIG. 19, an embodiment of the present disclosure is shown wherein there are a series of at leas three pins extending dorsally from the dorsal face of computer receptacle 100. These act as contact points against which a substantially planar computer may be retained at an angle theta such that the computer may be positioned in an inclined manner thereupon.

The aforementioned components of the present disclosure may be, unless otherwise noted, substantially manufactured from rigid materials known in the art including, but not limited to natural and synthetic resins, polymers, fibers, metals, and their composites. These methods include the various types of forming, molding, machining, etc. known in the manufacturing arts.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A computer receptacle comprising;
a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the ventral face thereof has a surface configured to be rested comfortably upon the lap of a user.

2. The computer receptacle of claim 1, wherein the engagement portion further comprises a lateral trough that traverses a substantial portion of the breadth of the receptacle.

3. The computer receptacle of claim 1, wherein the distance between the opposing walls or a portion thereof may be decreased by a mechanism selected from, a bolt threaded into one of the walls, an eccentrically hinged lever pivotably coupled to one of the walls, or inserts having varying thickness.

4. The computer receptacle of claim 1, wherein there is a plurality of keys disposed upon the proximal-end portion of the dorsal face of the body, and the keys are electronically connected to the computer to provide input thereto.

5. The computer receptacle of claim 4, wherein the means of electronic connection is selected from one of the following; a bluetooth connection, an infra-red connection, a wired usb connection, a wired proprietary connection.

6. The computer receptacle of claim 1, wherein there is a keyed slot disposed upon the ventral face of the body and operatively configured for receiving a stand therein.

7. The computer receptacle of claim 1, wherein the body has an electrical connector operatively configured to provide electrical, audio, or data communication with a source external to the computer receptacle.

8. The computer receptacle of claim 7, wherein the connector is selected from the group of, a wire and plug protruding from the body, a plug protruding from the body, at least two electrical contacts disposed upon the body, or an inductive coil.

9. The computer receptacle of claim 1, wherein the ventral surface comprises at least one of the following; a padded portion of material providing a more complaint surface than the remainder of the receptacle, a portion of natural or synthetic fabric, at least one detent shaped to accommodate a portion of the thigh of a user, a textured surface comprised of a pattern of embosses or detents along the ventral face of the receptacle.

10. A computer receptacle comprising;
a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the opposing walls may be radially displaced relative to the remainder of the body about coaxial pivots A and B disposed upon opposing sides of the body, wherein one of the pivots further comprises a toothed gear, and there is a complimentary toothed arc disposed upon the body which may be temporarily engaged upon the gear, thereby releasably fixing the angle of incidence of the electronic device relative to the body; and the ventral face thereof has a surface configured to be rested comfortably upon the lap of a user.

11. The computer receptacle of claim 10, wherein there is a spring biasing the arc towards the gear.

12. The computer receptacle of claim 10, wherein there is a spring biasing the arc away from gear.

13. The computer receptacle of claim 10, wherein there is an eccentrically hinged lever pivotably coupled to the body, with the lever having a bearing face A such that at one extreme of the lever's rotation, A engages the arc against the gear and at its other extreme of the lever's rotation, withdraws the arc from contact with the gear.

14. The computer receptacle of claim 10, wherein there is a plurality of keys disposed upon the proximal-end portion of the dorsal face of the body, and the keys are electronically connected to the computer and providing electronic input.

15. The computer receptacle of claim 14, wherein the means of electronic connection is selected from one of the following; a bluetooth connection, an infra-red connection, a wired usb connection, a wired proprietary connection.

16. The computer receptacle of claim 14, wherein there is a keyed slot disposed upon the ventral face of the body and operatively configured for receiving a stand therein.

17. A computer receptacle comprising;
a substantially planar body having a computer engagement portion disposed upon the distal end of the ventral surface thereof, wherein the engagement portion comprises two opposing, substantially parallel walls offset from the ventral face thereof and operatively configured to removably retain the computer therebetween, and the distance between the opposing walls or a portion thereof may be decreased by a mechanism selected from, a bolt threaded into one of the walls, an eccentrically hinged lever pivotably coupled to one of the walls, or inserts having varying thickness, and the opposing walls may be radially displaced relative to the remainder of the body about coaxial pivots A and B disposed upon opposing sides of the trough, wherein one of the pivots further comprises a toothed gear, and there is a complimentary toothed arc disposed upon the body which may be temporarily engaged upon the gear, thereby releasably fixing the angle of incidence of the electronic device relative to the body; and the ventral face thereof has a surface configured to be rested comfortably upon the lap of a user.

18. The computer receptacle of claim 17, wherein there are a plurality of keys disposed upon the dorsal surface of the body and electronically connected to the computer.

19. The computer receptacle of claim 1, wherein the angle of incidence between the parallel walls and the body is adjustable by means of a selectively engageable, radially hinged mechanism.

20. The computer receptacle of claim 17, wherein the distance between the opposing walls or a portion thereof may be decreased by a mechanism selected from, a bolt threaded into one of the walls, an eccentrically hinged lever pivotably coupled to one of the walls.
